(19) United States
(12) Patent Application Publication
(10) Pub. No.: US 2010/0231266 A1
(43) Pub. Date: Sep. 16, 2010

(54) LOW VOLTAGE AND LOW POWER DIFFERENTIAL DRIVER WITH MATCHING OUTPUT IMPEDANCES

(75) Inventor: Madhuban Kishor, Bangalore (IN)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/293,811

(22) PCT Filed: Mar. 21, 2007
(86) PCT No.: PCT/IB07/50998

§ 371 Date: Sep. 26, 2008

Related U.S. Application Data
(60) Provisional application No. 60/786,452, filed on Mar. 27, 2006.

(51) Int. Cl. H03B 1/00

(52) U.S. Cl. 327/108

(57) ABSTRACT

The present invention provides a system and a method for driving a differential signal which includes a differential data input, a plurality of switches coupled to a current source for steering current depending on the differential data input, a first differential output and a second differential output and a coupled to at least two of the plurality of switches and a first source follower and a second source follower coupled to the first differential output for controlling output impedance. This architecture prevents the common mode noise reflected from the driver from becoming a differential signal and meets the requirements of the LVDS and SubLVDS standard down till 1.62V. Also this architecture is capable of operating in Gbps range making it a high-speed differential driver with very low power.

The present invention generally relates to output driver circuitry for high speed data communications applications. More specifically, the present invention relates to the usage of low voltage differential signaling (LVDS) driver in the fields of telecommunications, video and other integrated circuits demanding transfer rates of Gbps for chip-to-chip, board-to-board and off-chip communications.

LVDS standard was developed in order to provide a low-power and low-voltage alternative to other high-speed input/output (I/O) interfaces. It is increasingly becoming a popular standard for point-to-point communications. A differential driver operating in Gbps range, like a LVDS is based on a current steering architecture which sources 3.5 mA current into a 100 ohms termination resistor connected between the differential pair at the receiver end to develop a 350 mV differential swing. The specification for single-ended DC output impedance for both inverting and non-inverting output is specified to be in the range of 40-140 ohms and the impedance at inverting and non-inverting output should match closely.

The reason for the impedance to be matched at the inverting and non inverting output terminals is explained as follows. The difference between driver output impedance and signal path impedance causes reflections of incident edges arriving at the driver output from the transmission media. These waves that disturb the signal direction come from two sources namely reflected signals and common-mode noise coupled onto the interconnection. To prevent common-mode noise reflected from the driver output from becoming a differential signal, the output impedance of the inverting and non-inverting outputs should be closely matched.

The CMOS090 LVDS SPM library of Philips™ gives a design for the differential driver, which meets all requirements of IEEE LVDS standard for a typical VDDE of 3.3V. The design provides an output voltage high-output voltage low (VOH-VOL) of 1.37V-1.03V and also provides single-ended DC output impedances in the range of 40-140 ohms. It can operate at a VDDE of 2.5V for subLVDS standard which has a VOH-VOL of 0.96V-0.8V in CMOS090 process. But below a VDDE of 2.5V, the differential driver does not provide DC output impedance in the range of 40-140 ohms.

U.S. Pat. No. 6,867,618, entitled “Voltage mode differential driver and method” by Ning Li, et al discloses a differential driver. The differential driver as disclosed in this patent operating below 1.8V power supply does not provide DC output impedance in the range of 40-140 ohms. Moreover, the inverting and non-inverting output impedances do not match and also do not track across process and temperature. Other publications about differential drivers are “LVDS I/O Interface of Gb/s-per-Pin Operation in 0.35 um CMOS” by Andrea Boni et al.; IEEE Journal of Solid-State Circuits, Vol. 36, No. 4, April 2001; pp. 706-711.

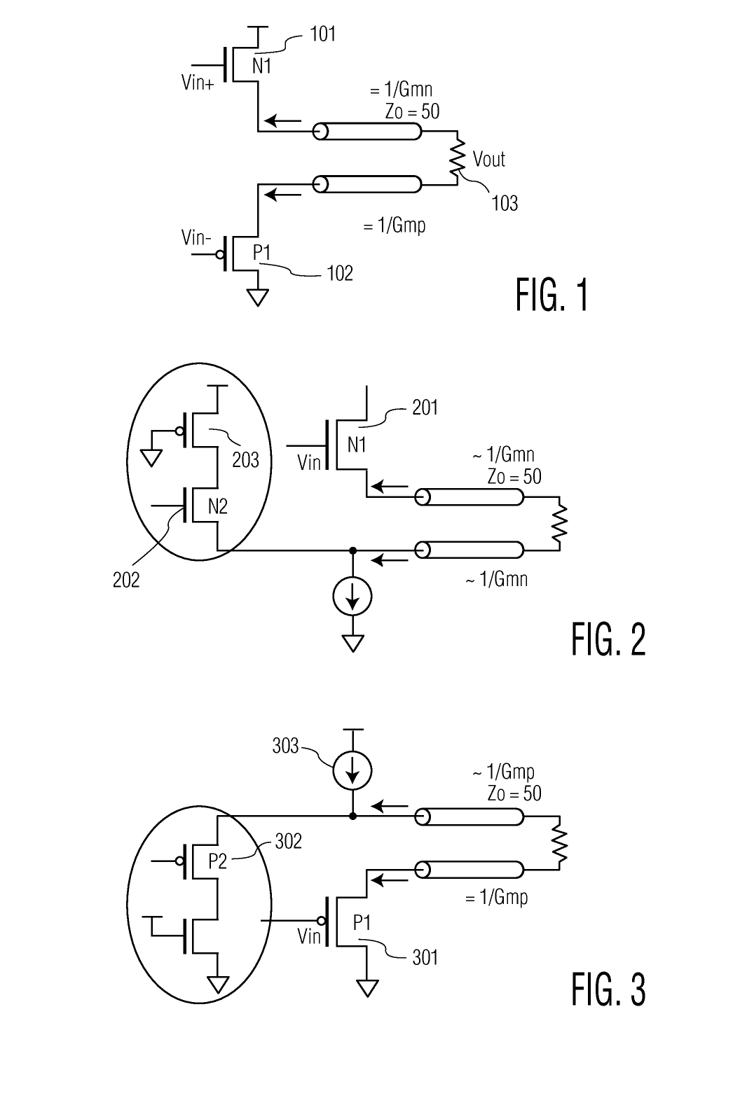

FIG. 1 is an illustration of a prior art LVDS driver. A single-leg of the source follower based differential driver is shown in FIG. 1. The differential driver includes an N-type transistor N1 101, a P-type transistor P1 102, and a termination resistor 103. The termination resistor 103 forms the output nodes for the differential driver. The DC output impedance specification of LVDS requires the driver to have a source follower configuration. The design should source almost constant current, but should act as a voltage mode driver and provide low output impedance at both the inverting and non-inverting output.

The minimum VDDE needed for this architecture is,

VDDE(min)=VOH+Vgs(N1) (=Vtn+overdrive)

For a 2.5V device in 90 nm process, the worst case V_{T} (slow process and low temp.) is ˜0.75. With 250 mV overdrive, VDDE (min)=VOH+1.0V. Also, the NMOS transistor N1 101 is subjected to severe body effect which increases its V_{T}. The value of V_{T} of NMOS transistor N1 101 can be lowered by 100 mV-200 mV in a triple-well process by connecting source and substrate together. But connecting source and substrate together will make the design process-dependent and the above limitation of VDDE will still hold good.

Another disadvantage of this circuit is that the output impedance when driving high is dependent on NMOS characteristic, while driving low is dependent on PMOS characteristic. Hence, over different skew process corners (Slow NMOS and Fast PMOS or vice versa), the output impedances are mismatched.

FIG. 2 is another illustration of a prior art LVDS driver. A different type of architecture which tries to overcome the problem of mismatched inverting and non-inverting output impedance is illustrated in FIG. 2. This architecture includes NMOS source followers namely, N1 201, N2 202 at both ends of the output and a PMOS switch 203. The additional source follower N2 202 (shown inside the ellipse) is coupled to both the outputs in a differential buffer, but the NMOS source follower coupled to output driving low is conducting while the other NMOS source follower is OFF. This architecture also has the VDDE limitation.

The current driving methods of a differential signal gives a mismatched output impedance below a VDDE of 2.5 V for LVDS and 1.8 V for subLVDS standards. Hence there exists a need for driving a differential signal below a VDDE 2.5 V for LVDS and below 1.8 V for subLVDS standards with matching impedances at the inverting and non-inverting outputs.

In an example embodiment of the present invention, a differential driver is provided. The differential driver includes a differential data input, a plurality of switches coupled to a current source for steering current depending on the differential data input, a first differential output and a second differential output, and a first source follower and a second source follower coupled to the first differential output and the second differential output for controlling output impedance.

In another example embodiment of the present invention, a method of driving a signal is provided. The method includes the steps of providing a differential data input to a differential driver, providing a plurality of switches coupled to a current source for steering current depending on the differential data input, and providing a first source follower and a second source follower coupled to a first differential output and a second differential output for controlling impedance.

In another example embodiment of the present invention, a differential driver is provided. The differential driver includes a differential data input, a plurality of switches coupled to a current source for steering current depending on the differential data input, a bias circuit for generating appropriate bias voltage inputs to the differential driver, a first differential output and a second differential output, and a first source follower and a second source follower coupled to the first differential output and the second differential output for controlling output impedance.

The above summary of the present invention is not intended to represent each disclosed embodiment, or every aspect, of the present invention. Other aspects and example embodiments are provided in the figures and the detailed description that follows.

The invention may be more completely understood in consideration of the following detailed description of various embodiments of the invention in connection with the accompanying drawings, in which:

FIG. 1 is an illustration of a prior art LVDS driver.

FIG. 2 is another illustration of a prior art LVDS driver.

FIG. 3 is an illustration of a single leg of a LVDS driver according to an embodiment of the present invention.

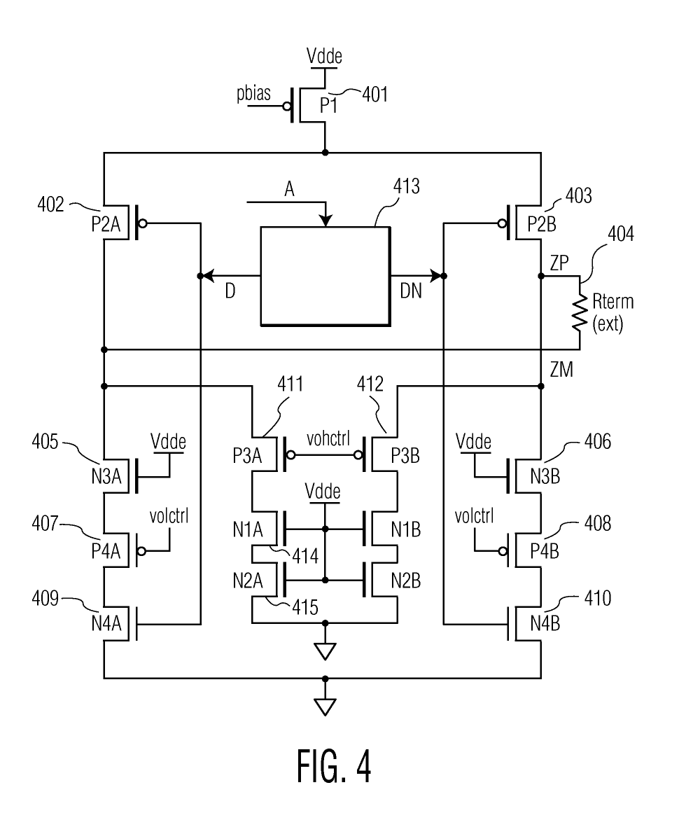

FIG. 4 is a structure of differential driver according to an embodiment of the present invention.

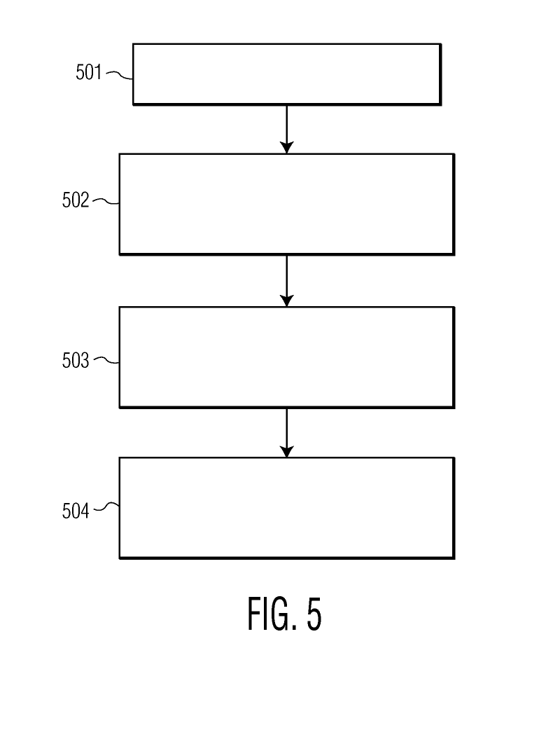

FIG. 5 is an illustration of a method for driving a signal according to the present invention.

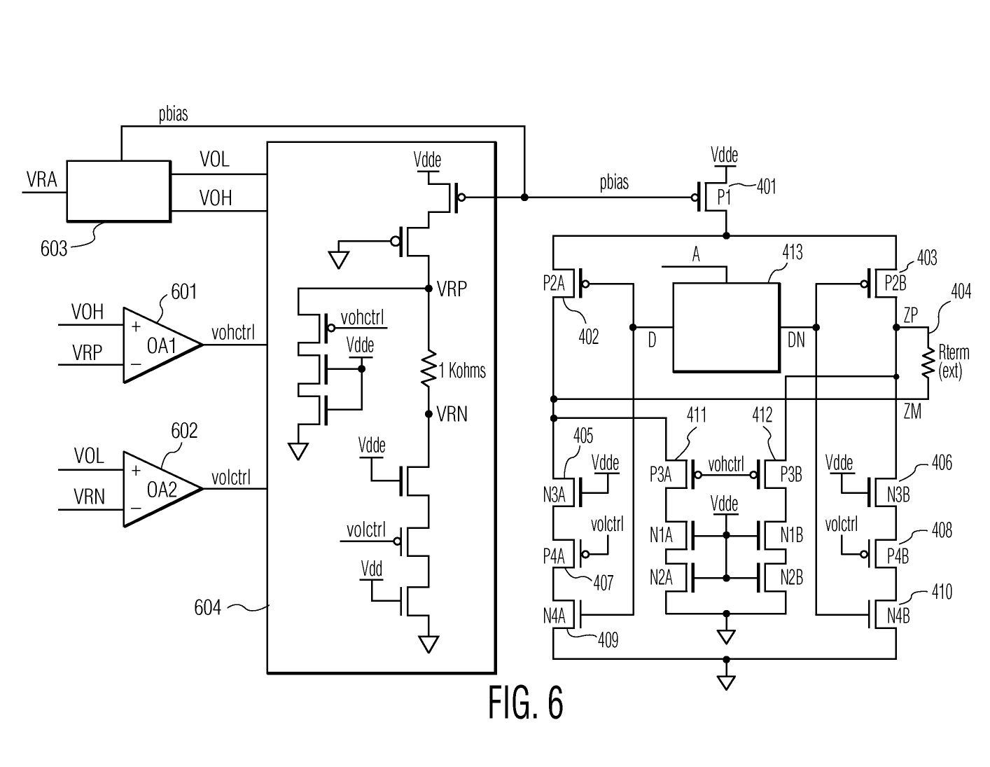

FIG. 6 is conceptual diagram of a differential driver with a bias circuit according to another embodiment of the present invention.

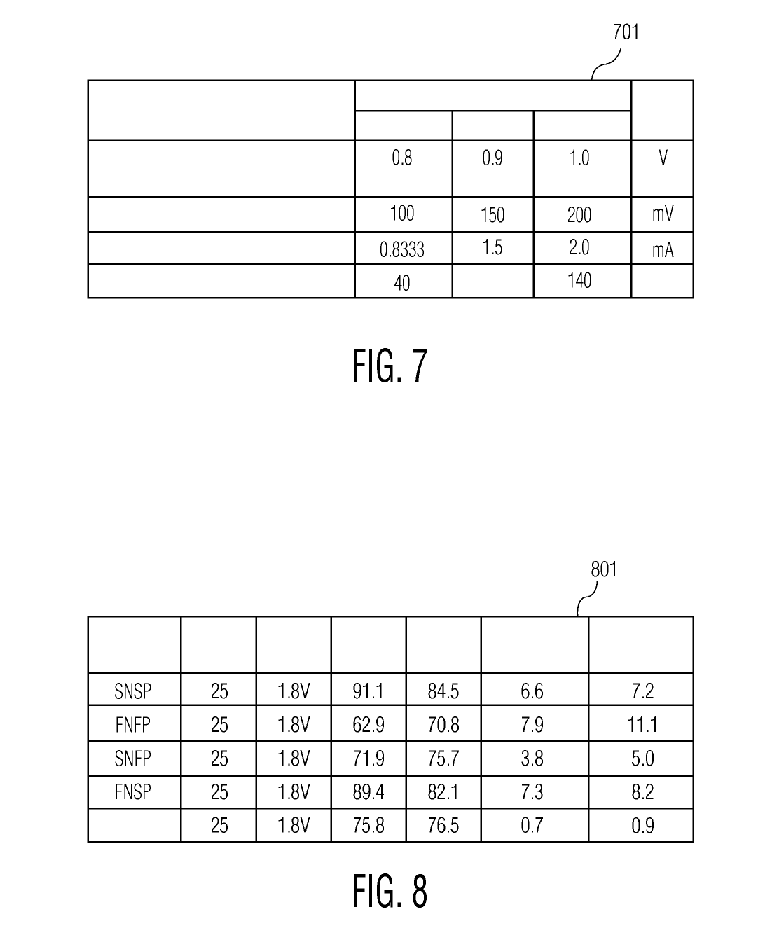

FIG. 7 is a table illustrating the DC specifications for SubLVDS standard.

FIG. 8 is a table illustrating the output impedances after simulation according to the method of present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

FIG. 3 is an illustration of a single leg of a LVDS driver according to an embodiment of the present invention. The circuit includes a pair of PMOS transistors P1 301 and P2 302 coupled in voltage control voltage source mode for controlling the VOH and VOL levels, a current source 303.

The PMOS source followers P1, 301 and P2, 302 at both ends of the output provides low output impedance. The low impedances at both outputs make the differential driver capable of high-speed operation. The impedance at inverting and non-inverting outputs is determined by the PMOS transistors P1, 301 and P2, 302 and hence, the matching between them is good even for skew process corners (slow PMOS and fast NMOS or vice versa).

The minimum VDDE needed for this architecture is,

VDDE(min)=VOH+Vds(for current source)

The VOL of the circuit needs to be greater than the Vtp of PMOS transistor P1 301 in the circuit. This requirement is easily met for popular high-speed standards like SubLVDS and LVDS. The architecture illustrated in FIG. 3 solves the problem of VDDE limitation (low voltage) as well as provides matching impedances at inverting and non-inverting outputs.

FIG. 4 is a structure of differential driver according to an embodiment of the present invention. The concept explained in FIG. 3 is used to build a differential driver for LVDS and SubLVDS standards. The differential driver includes a top PMOS current source transistor P1 401 and then two PMOS switches P2A 402 and P2B 403 in the top-half portion to steer current depending on data polarity. An external resistor 404 is coupled between drains of PMOS switches P2A 402 and P2B 403 which form the output nodes of the differential driver.

In the bottom portion, the outputs are coupled to the drain of NMOS electrostatic discharge (ESD) devices, N3A 405 and N3B 406 which are always in ON state and sized such that they are not dominant factors in the output impedance of the differential driver. The transistors N3A 405 and N3B 406 protect the lower devices against over-voltage on the outputs, when the pad is tri-stated. Transistors N3A 405 and N3B 406 are coupled to PMOS source followers P4A 407 & P4B 408, and then to NMOS switches, N4A 409 and N4B 410. The source followers give low impedance for the output driving low. It also controls the VOL level of the differential driver.
Considering ZP=“HIGH” and ZM=“LOW”, the output impedance for output driving low is given by the equation:

R_{OLOW}=1 /gm_{N3B}+1/gm_{P4B}+1/gm_{N4B}

Where, 1/gm_{N3B} and 1/gm_{N4B} are triode ON resistance of the NMOS transistors N3B 406 and N4B 410. Hence, these transistors are sized such that R_{OLOW} is only dependent on PMOS transistors P4A 407, P4B 408.

Additional PMOS source followers P3A 411 and P3B 412 are coupled to the output, out of which the source follower coupled to output driving HIGH conducts while the other is in OFF state. The source follower which conducts when coupled to output driving HIGH provides low impedance for the output driving HIGH and also controls the VOH level of the differential driver. So, ignoring the high output impedance of current source transistor P1 401, the output impedance for the output driving high is given by the equation:

R_{OHIGH}=1/gm_{P3A}+1/gm_{N1A}+1/gm_{N2A}

Where, 1/gm_{N1A} and 1/gm_{N2A} are triode ON resistance of respective NMOS transistors N1A 414 and N2A 415 and they are sized such that R_{OHIGH} is only dependent on PMOS transistors P3A 411 and P4B 412.

The single-ended to differential converter block 413 converts the single-ended signal into a differential signal. The single-ended to differential converter block 413 operates on core VDD supply and provides the pre-driver function as well, while the output driver stage and bias circuitry operates on VDDE and there is no level conversion required for the data signals D and DN.

Because of PMOS source followers coupled to inverting and non-inverting outputs, low impedances are achieved. These impedances are dependent on only one type of transistor used and hence, they track across process and temperature changes. The use of PMOS transistors in the source follower and current source in a strategic way also makes the design VDDE independent and provides accurate VOH/VOL control.

The PMOS transistor P1 401 acting as constant current source is biased from a bias circuitry whose output current is Iₒᵤₜ=Vref/R. Vref is the bandgap reference voltage and hence is almost constant across PVT variations. The resistor R is implemented with poly resistor and varies ˜20% across process. But even with this current variation, the swing of the differential driver is maintained within a certain range. Also, if an external precision resistor is provided, the current in the PMOS current source P1 401 would be constant across process voltage temperature (PVT).

FIG. 5 is an illustration of a method for driving a signal according to the present invention. A single-ended to differential converter 413 converts the single-ended signal (which is the data input) into a differential signal and then it is provided to the differential driver 501. A plurality of switches is provided for steering the current according to the data polarity. The switches include a first pair (P-type) and a second pair (N-type) of transistors. The gate of the first transistor of the first pair is coupled to the gate of the first transistor of the second pair.

The gate of the second transistor of the first pair is coupled to the gate of the second transistor of the second pair. The first transistor of the first pair and the first transistor of the second pair (same holds for second transistors of the first and second pairs) are connected to the differential data signal coming from the single ended to differential converter. The first pair of transistors (P-type) is coupled to a current source transistor 502. The output nodes are taken from an external termination resistor coupled to the switches. There is a pair of source followers coupled to the outputs for controlling impedances 503, 504. Both the source followers (a first source follower and a second source follower) are coupled to the output nodes.

The pair of source followers (both P-type) includes a first pair of transistors and a second pair of transistors. The first pair of transistors of the first source follower and second pair of transistors of the second source follower are of the same type. At least one of the transistors of the first pair of transistors is ON while the other transistor is OFF, and at least one of the transistors of the second pair of transistors is ON while the other transistor is OFF. Because of PMOS source followers coupled to inverting and non-inverting outputs, low impedances are achieved. These impedances are dependent on only one type of transistor used and hence, they track across process and temperature changes. The use of PMOS transistors in the source follower and current source in a strategic way also makes the design VDDE independent and provides accurate VOH/VOL control (as in FIG. 4).

FIG. 6 is conceptual diagram of a differential driver with a bias circuit according to another embodiment of the present invention. The differential driver structure discussed in FIG. 4 with associated pre-driver and bias circuitry is shown in FIG. 6. A replica stack 604 of the driver stage is utilized to sense the effect of process, voltage and temperature variations on the output levels and they are feedback to the bias circuitry for correcting the bias voltages feeding the driver and its replica stack 604. The implementation is shown for C065 process with 2.5 V thick gate devices and the normal thin-gate devices. Core VDD is 1.2V and VDDE is 1.8V and the expected VOH=0.96V while VOL=0.8V (for SubLVDS).

The source follower transistors P3A 411, P3B 412 and P4A 407, P4B 408 are controlled by the bias circuitry. To generate proper bias voltages, a replica 604 of the output stage is created which develops the same voltages as the driver at the corresponding nodes. The replica stack 604 takes 1/10th of the current in the driver stage and hence the corresponding devices are sized accordingly ( 1/10th of transistor sizes in the differential driver). The voltages from the replica stack 604 are fed to a bias circuitry, which compares them with the expected values and generates the control voltages.

The bias circuitry includes a pair of operational amplifiers OA1 601, OA2 602 and a reference generator 603. The reference generator 603 generates expected VOH, VOL values from the bandgap reference voltage by using an operational amplifier and feedback resistors. The ratio of the resistors decides the VOH, VOL values. Hence the expected VOH, VOL are derived from bandgap reference voltages and resistor ratios, and they are almost constant across PVT. Operational amplifiers OA1 601 and OA2 602 compare the replica stack voltages with these VOH and VOL values and generate control voltages. Thus, driver output levels are accurately controlled.

The functioning of the above circuit is explained below. Considering the condition when ZP=HIGH and ZM=LOW, the transistors which conduct are P2B 403, N3A 405, P4A 407 and N4A 409. The PMOS transistor P1 401 sources a constant current in the normal operation. The path through source follower transistor P3B 412 is also ON. The single-ended signal ‘A’ coming from the chip core is passed to the single-ended to differential converter block 413 which converts single-ended signal to differential signal. The output of this block is at core levels (0 to VDD). Thus no additional level shifting is required for these differential signals.

Current source P1 401 sources a constant current which is steered through the external termination resistor 404 of 100 ohms by the PMOS switch P2B 403. P4A 407, P4B 408 is the pair of second source follower, out of which the one coupled to output driving low (P4A 407) conducts while the other is OFF because of the NMOS switches coupled at the bottom. The gate control of PMOS transistors P1 401, P4A 407, P4B 408 P3A 411, and P3B 412 are generated from the bias circuitry. The node voltages “VRP” and “VRN” are compared with the expected VOH and VOL generated by the bias circuitry from the bandgap reference voltage input “VRA”. Operational amplifiers OA1 601 and OA2 602 compare the replica voltages and the expected VOH, VOL and give an output “vohctrl” and “volctrl”. When the output switches, i.e. ZP=LOW and ZM=HIGH, the transistors which conduct are P2A 402, N3B 406, P4B 408 and N4B 410. Thus, the direction of current through the external resistor 404 is reversed, developing an output voltage of opposite polarity. P3A 411 is conducting while P4B 408 is OFF.

FIG. 7 is a table illustrating the DC specifications for SubLVDS standard 701. The circuit has been designed for nominal V_{CMF}=0.88V, VOH=0.96V and VOL=0.8V with a nominal swing of 160 mV.

FIG. 8 is a table illustrating the output impedances after simulation according to the method of present invention 801. It can be clearly understood from the figure that the output impedance is within the specification and match closely. It also shows that even with skew corners, the impedance at inverting and non-inverting outputs match closely.

While the present invention has been described with reference to several particular example embodiments, those skilled in the art will recognize that many changes may be made thereto without departing from the spirit and scope of the present invention, which is set forth in the following claims.

The present invention will find its industrial applications for supporting LVDS and SubLVDS standards. These standards form part of the Electrical layer specifications of several high speed data bus specifications like PCI Express®, RapidIO™, HyperTransport™, Infiniband®, etc which are used in major bandwidth hungry communications networks.

1. A differential driver comprising:
a differential data input;
a plurality of switches coupled to a current source for steering current depending on said differential data input;
a first differential output and a second differential output, wherein a resistor coupled between at least two of said plurality of switches forms said first differential output and said second differential output; and
a first source follower and a second source follower coupled to the first differential output and the second differential output for controlling output impedance.

2. The differential driver as in claim 1, further comprising of: a bias circuit for supplying bias input voltages to said first source follower and said second source follower and said current source.

3. The differential driver as in claim 1, wherein said plurality of switches further comprising of: a first pair and a second pair of transistors, wherein a gate of a first transistor of said first pair coupled to a gate of a first transistor of said second pair; and a gate of a second transistor of the first pair coupled to a gate of a second transistor of the second pair.

4. The differential driver as in claim 1, wherein said first source follower comprises a first pair of transistors and said second source follower comprises a second pair of transistors.

5. The differential driver as in claim 4, wherein said first pair of transistors of the first source follower and said second pair of transistors of the second source follower are of a same type, and at least one of the transistors of the first pair of transistors is ON while the other transistor is OFF, and at least one of the transistors of the second pair of transistors is ON while the other transistor is OFF.

6. The differential driver as in claim 1, further comprises a plurality of protecting transistors, wherein source of said plurality of protecting transistors are coupled to the first pair of transistors of the first source follower and drain of the plurality of protecting transistors are coupled to the second pair of transistors of the second source follower, the protecting transistors for protecting source followers against over voltage on the outputs.

7. The differential driver as in claim 1, wherein said differential data input comprises of an output from a single ended to differential converter for converting single ended signal to differential signal.

8. The differential driver as in claim 3, wherein the first pair of transistors comprises a P-type transistor and the second pair of transistors include an N-type transistor.

9. The differential driver as in claim 3, wherein the first pair of transistors of the first source follower and the second pair of transistors of the second source follower comprise P-type transistors.

10. A method of driving a signal comprising the steps of:
providing a differential data input to a differential driver;
providing a plurality of switches coupled to a current source for steering current depending on said differential data input;
providing a resistive means coupled between at least two of said plurality of switches forming a first differential output and a second differential output; and
providing a first source follower and a second source follower coupled to said first differential output and said second differential output for controlling impedance.

11. The method of claim 10, further comprising the steps of: providing a bias circuit for supplying bias input voltages to said first source follower and said second source follower and said current source.

12. The method of claim 10, wherein said providing a plurality of switches further comprising the steps of: providing a first pair and a second pair of transistors, wherein a gate of a first transistor of said first pair coupled to a gate of a first transistor of said second pair; and a gate of a second transistor of the first pair coupled to a gate of a second transistor of the second pair.

13. The method of claim 10, wherein said first source follower further comprises a first pair of transistors; and said second source follower further comprises a second pair of transistors.

14. The method of claim 13, wherein said first pair of transistors of the first source follower and said second pair of transistors of the second source follower are of the same type, and at least one of the transistors of the first pair of transistors is ON while the other transistor is OFF, and at least one of the transistors of the second pair of transistors is ON while the other transistor is OFF.

15. The method of claim 10, further comprising the steps of: providing a plurality of protecting transistors for protecting source followers against over voltage on the outputs, wherein source of said plurality of protecting transistors are coupled to the first pair of transistors of the first source follower and drain of the plurality of protecting transistors are coupled to the second pair of transistors of the second source follower.

16. The method of claim 12, wherein the first pair of transistors includes a P-type transistor and the second pair of transistors include an N-type transistor.

17. The method of claim 12, wherein the first pair of transistors of the first source follower and the second pair of transistors of the second source follower include P-type transistors.

18. A differential driver comprising:
a differential data input;
a plurality of switches coupled to a current source for steering current depending on said differential data input;
a bias circuit for generating appropriate bias voltage inputs to said differential driver;
a first differential output and a second differential output wherein a resistor coupled to said plurality of switches form said first differential output and said second differential output; and
a first source follower and a second source follower coupled to the first differential output and the second differential output for controlling output impedance.

19. The differential driver as in claim 18, wherein said bias circuit further comprising of: a means of generating a replica stack voltage in the differential driver; a reference generator for generating expected voltage inputs; and a pair of operational amplifiers for comparing said replica stack voltage and said expected voltage inputs for generating accurate control voltage inputs to the differential driver.

20. The differential driver as in claim 18, wherein said plurality of switches further comprising of: a first pair and a second pair of transistors, wherein a gate of a first transistor of said first pair coupled to a gate of a first transistor of said second pair; and a gate of a second transistor of the first pair coupled to a gate of a second transistor of the second pair.

21. The differential driver as in claim 18, wherein said first source follower further comprising of a first pair of transistors; and said second source follower further comprising of a second pair of transistors.

22. The differential driver as in claim 21, wherein said first pair of transistors of the first source follower and said second pair of transistors of the second source follower are of the same type, and at least one of the transistors of the first pair of transistors is ON while the other transistor is OFF, and at least one of the transistors of the second pair of transistors is ON while the other transistor is OFF.

23. The differential driver as in claim 18, further comprises of a plurality of protecting transistors, wherein source of said plurality of protecting transistors are coupled to the first pair of transistors of the first source follower and drain of the plurality of protecting transistors are coupled to the second pair of transistors of the second source follower, the protecting transistors for protecting source followers against over voltage on the outputs.

24. The differential driver as in claim 18, wherein said differential data input comprises of an output from a single ended to differential converter for converting single ended signal to differential signal.

25. The differential driver as in claim 20, wherein the first pair of transistors includes a P-type transistor and the second pair of transistors include an N-type transistor.

26. The differential driver as in claim 20, wherein the first pair of transistors of the first source follower and the second pair of transistors of the second source follower include P-type transistors.
